(19) United States
(12) Patent Application Publication
(10) Pub. No.: US 2026/0193784 A1
(43) Pub. Date: Jul. 9, 2026

(54) FLOW CONTROL RING ASSEMBLY AND METHOD OF USING SAME

(71) Applicant: ASM IP Holding B.V., Almere (NL)

(72) Inventors: Qichao Hu, Tempe, AZ (US); Shubham Garg, Gilbert, AZ (US); Nirmal Gokuldas Waykole, Tempe, AZ (US); YoungChol Byun, Temp, AZ (US)

(21) Appl. No.: 19/437,440

(22) Filed: Dec. 31, 2025

Related U.S. Application Data
(60) Provisional application No. 63/741,587, filed on Jan. 3, 2025.

(51) Int. Cl. C23C 16/455

(52) U.S. Cl. CPC C23C 16/45563

(57) ABSTRACT

A flow control ring assembly for a gas-phase reactor, the reactor, a reactor system, and a method are disclosed. The flow control ring assembly can be configured to mitigate particle formation during substrate processing. The flow control ring assembly includes a spacer plate, a flow control ring, and a chamber isolation ring.

### CROSS-REFERENCE TO RELATED APPLICATIONS

This application is a nonprovisional of, and claims priority to and the benefit of, U.S. Provisional Ser. No. 63/741,587 , filed Jan. 3, 2025 and entitled “FLOW CONTROL RING ASSEMBLY AND METHOD OF USING SAME,” which is hereby incorporated by reference herein.

### FIELD

Examples are described that relate to a flow control ring assembly and a reactor including a flow control ring assembly, as well as a method for use of the flow control ring assembly and reactor.

### BACKGROUND

A substrate processing apparatus, such as a gas-phase reactor, can often include a first (e.g., upper) chamber space for processing a substrate and a second (e.g., lower) chamber space for loading and unloading the substrate. During processing, the first chamber can be isolated from the second chamber using a flow control ring assembly. The flow control ring assembly can form a substantial seal between the first chamber and the second chamber to mitigate flow of reaction gases from the first chamber to the second chamber. The undesired flow of reaction gases between the chamber spaces can cause particle contamination and/or slower processing of the substrates.

Under some process conditions, such as relatively high pressure or relatively high gas flowrate swings, the flow control ring assembly may not provide desired isolation between the first chamber and the second chamber. Additionally or alternatively, the flow control ring assembly may cause unwanted particle formation. Accordingly, improved flow control ring assemblies are generally desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a flow control ring assembly for a gas-phase reactor, a reactor including a flow control ring assembly, and a method of using the flow control ring assembly and reactor. Various examples of the flow control ring assembly, reactor, and method provide for less particle formation within a reactor. For example, use of a flow control ring assembly and/or reactor as described herein can mitigate particle formation that might otherwise occur—e.g., in cases in which a relatively large pressure swing occurs within a reaction (e.g., upper) chamber of the reactor during substrate processing and/or in which a relatively large (e.g., greater than about 5-50 standard liters per minute (SLM)) flowrate swing occurs in the reaction chamber during substrate processing and/or in which a pressure differential between a first (e.g., upper) chamber and a second (e.g., lower) chamber is relatively high With prior flow control ring assemblies, during such relatively high pressure and/or flowrate changes or pressure differentials, portions or rings of the flow control ring assembly could vibrate or chatter during processing. The vibrating or chattering, in turn, can lead to particle formation, which, in turn, can lead to defects on substrates that are processed. Additional aspects are set forth in the description that follows will be apparent from the description or may be learned by practice of the presented embodiments of the disclosure.

According to one or more embodiments, a flow control ring assembly for a gas-phase reactor is provided. In accordance with examples of these embodiments, a flow control ring assembly includes a spacer plate, a flow control ring, and a chamber isolation ring. An exemplary spacer plate includes a spacer plate top surface, a spacer plate bottom surface, an inner spacer plate surface therebetween, and a ledge defined by an inner ledge surface extending from the spacer plate top surface to a top ledge surface, wherein the top ledge surface extends between the inner spacer plate surface and the inner ledge surface. An exemplary flow control ring includes a flow control ring bottom surface, a flow control ring top surface, an inner perimeter surface between the flow control ring bottom surface and the flow control ring top surface, and an outer perimeter surface between the flow control ring bottom surface and the flow control ring top surface. An exemplary chamber isolation ring is positioned radially interior the spacer plate and below the flow control ring bottom surface. In accordance with some examples of these embodiments, the chamber isolation ring includes a substantially planar chamber isolation ring top surface and a chamber isolation ring bottom surface. In accordance with further examples, the spacer plate includes a tapered surface between the inner spacer plate surface and the spacer plate bottom surface. In accordance with additional examples, a height between the spacer plate top surface and the top ledge surface is between about 6.5 mm and about 8.5 mm or between about 6 mm and about 6.5 mm. In accordance with yet further examples, a distance between the flow control ring bottom surface and the chamber isolation ring top surface is between about 2 and about 5 mm or between about 2.5 and about 3 mm. In accordance with yet additional examples, the flow control ring bottom surface includes a first section and a second section interior to the first section, wherein a height between the flow control ring top surface and the flow control ring bottom surface of the first section is less than a height between the flow control ring top surface and the flow control ring bottom surface of the second section. A distance between a chamber isolation ring outer surface and the inner spacer plate surface can be between about 3 mm and about 16 mm or between about 4 mm and about 14 mm. The chamber isolation ring bottom surface can include a first portion, a second portion, and a tapered third portion therebetween. The chamber isolation ring can include a chamber isolation ring inner perimeter surface and a chamber isolation ring outer perimeter surface, wherein a radial width between the chamber isolation ring inner perimeter surface and the chamber isolation ring outer perimeter surface is between about 13.5 mm and about 21.5 mm or between about 15.5 mm and about 20.5 mm. In accordance with further examples, a thickness between the chamber isolation ring top surface and the chamber isolation ring bottom surface in an inner region of the chamber isolation ring is greater than a thickness between the chamber isolation ring top surface and the chamber isolation ring bottom surface in an outer region of the chamber isolation ring.

In accordance with additional embodiments of the disclosure, a reactor includes a reaction chamber, a susceptor within the reaction chamber, and a flow control ring assembly, such as a flow control ring assembly described herein. In some cases, the reaction chamber is or includes an upper chamber.

In accordance with yet additional embodiments of the disclosure, a method includes providing a substrate within a reaction chamber comprising a flow control ring assembly, such as a flow control ring assembly described herein. The method can further include changing a total gas flowrate within the reaction chamber during processing of the substrate. For example, the flowrate can change from less than 100 SLM to greater than 4 SLM in a relatively short period (e.g., less than about 0.5 seconds).

These and other embodiments will become readily apparent to those skilled in the art from the following detailed description of certain embodiments having reference to the attached figures; the invention is not limited to any particular embodiment(s) disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates a reactor system in accordance with one or more examples of the disclosure.

FIG. 2 illustrates a cross-sectional view of a reactor in accordance with one or more examples of the disclosure.

FIG. 3 illustrates an enlarged view of a portion of a flow control ring assembly in accordance with one or more examples of the disclosure.

FIG. 4 illustrates a spacer plate in accordance with examples of the disclosure.

FIG. 5 illustrates an enlarged view of a section of a spacer plate in accordance with examples of the disclosure.

FIG. 6 illustrates a chamber isolation ring in accordance with examples of the disclosure.

FIG. 7 illustrates an enlarged view of a section of a chamber isolation ring in accordance with examples of the disclosure.

FIG. 8 illustrates a cross-sectional view of another reactor in accordance with one or more examples of the disclosure.

FIG. 9 illustrates an enlarged view of a portion of a flow control ring assembly in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As set forth in more detail below, various embodiments of the disclosure relate to a flow control ring assembly for a gas-phase reactor. The flow control ring assembly can be used to mitigate flow between a first (e.g., upper) chamber of a reactor and a second (e.g., lower) chamber of the reactor, while also mitigating particle formation. Use of flow control ring assemblies as described herein may be particularly beneficial when processing substrate with methods that include relatively large (e.g., greater than 70 Torr) changes in pressure within a relatively short time period (e.g., less than about 0.1 seconds) and/or relatively large (e.g., greater than 60 SLM) changes in gas flowrate in the upper chamber within a relatively short time period (e.g., less than about 0.1 seconds) and/or when a pressure difference between the upper chamber and the lower chamber is relatively high (e.g., greater than 70 Torr). Other exemplary flowrate differences and pressure differences are noted herein.

As used herein, the term “and/or” includes any and all combinations of one or more of the associated listed items. Expressions such as “at least one of,” when preceding a list of elements, modify the entire list of elements and do not modify the individual elements of the list.

As used herein, the term “substrate” may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

In this disclosure, the term “gas” may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space, and may include a seal gas, such as a rare gas.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. For example, the term about can refer to +/−20, 10, 5, 2, or 1 percent of a value. Further, in this disclosure, the terms including, comprising, constituted by and having and their equivalents can refer independently to typically or broadly comprising, consisting essentially of, or consisting of in some embodiments. In accordance with aspects of the disclosure, any defined meanings of terms do not necessarily exclude ordinary and customary meanings of the terms.

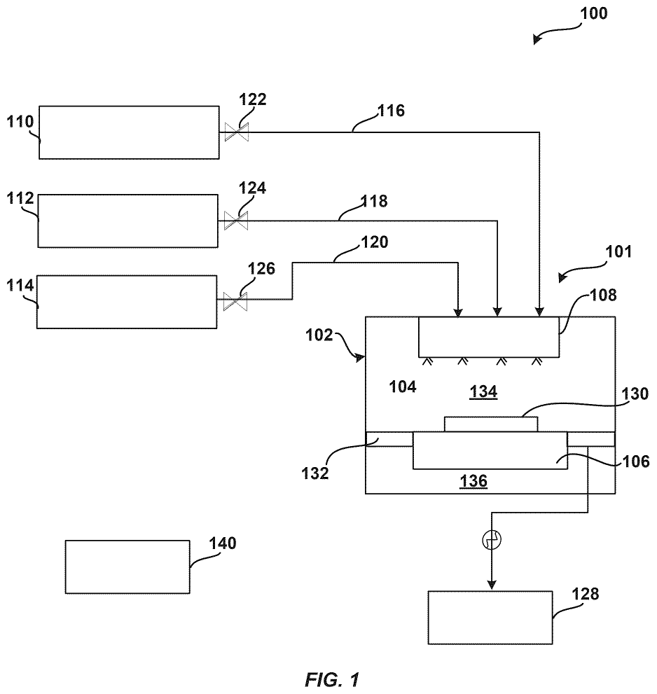

Turning now to the figures, FIG. 1 illustrates a reactor system 100 that includes a reactor 101 that includes a reaction chamber 102, a susceptor 106 to hold a substrate 130 during processing, and a fluid distribution system 108 (e.g., a showerhead) to distribute one or more reactants and/or precursors to a surface of substrate 130. In the illustrated example, reactor system 100 also includes one or more reactant and/or precursor sources 110, 112 and/or a carrier and/or purge gas source 114, fluidly coupled to a reaction space 104, within reaction chamber 102, via lines 116, 118, 120, and a flow control ring assembly 132. Reactor system 100 can also include valves and/or controllers 122, 124, 126 to control a flow of gas between sources 110, 112, 114 to reaction space 104. Reactor system 100 can also include a vacuum source (e.g., a vacuum pump) 128 fluidly coupled to the reaction space 104. Reactor system 100 can also include a controller 140 configured to cause components of reactor system 100 to move a substrate and/or to cause vacuum source to evacuate reaction space 104 and/or control valves and/or controllers 122, 124, 126 to provide gas from respective sources 110, 112, 114 to reaction space 104.

In accordance with examples of the disclosure, during operation of reactor system 100, substrate 130 can be loaded onto susceptor 106 in a lower chamber 136. Susceptor 106 can then move (e.g., upward) to place substrate 130 in an upper chamber 134/reaction space 104 during substrate processing. Flow control ring assembly 132 is configured to mitigate flow (e.g., for a substantial seal) between upper chamber 134 and lower chamber 136 and also mitigate particle formation that might otherwise occur. While the terms upper and lower chambers are used herein, any orientation of first and second chambers are to be considered within the scope of various examples of this disclosure.

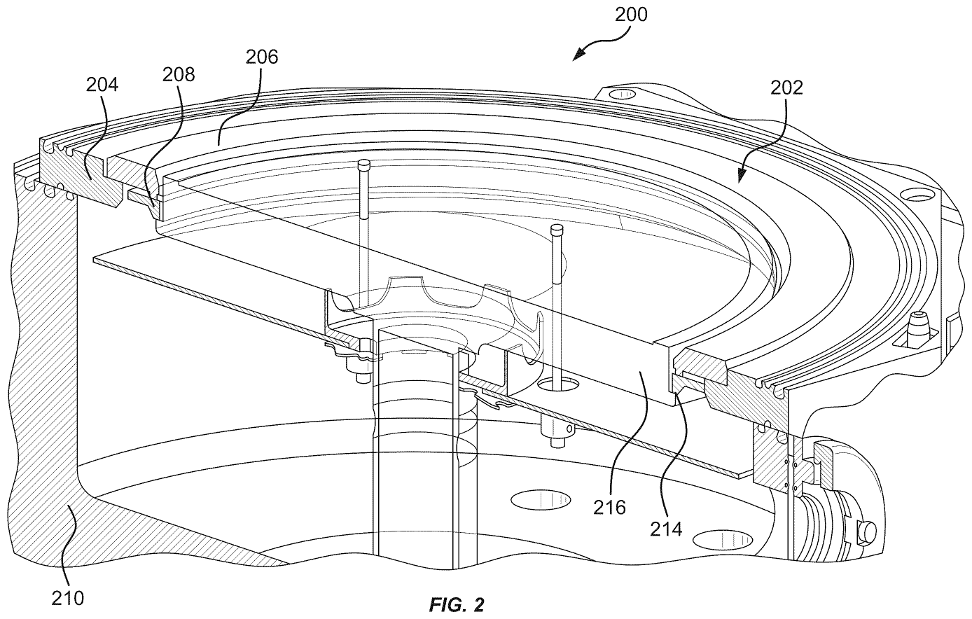

FIG. 2 illustrates a cross-sectional view of a reactor 200 and of a flow control ring assembly 202 in accordance with examples of the disclosure. Reactor 200 can be the same or similar to reactor 101 described above. Similarly, flow control ring assembly 202 can be the same or similar to flow control ring assembly 132, described above.

Flow control ring assembly 202 includes a spacer plate 204, a flow control ring 206, and a chamber isolation ring 208. In some embodiments, spacer plate 204 is attached to a chamber wall 210 of reactor 200. In some embodiments, flow control ring 206 rests on a ledge of spacer plate 204. In some embodiments, a chamber isolation ring 208 rests on a ledge 214 of susceptor 216, which can be the same or similar to susceptor 106.

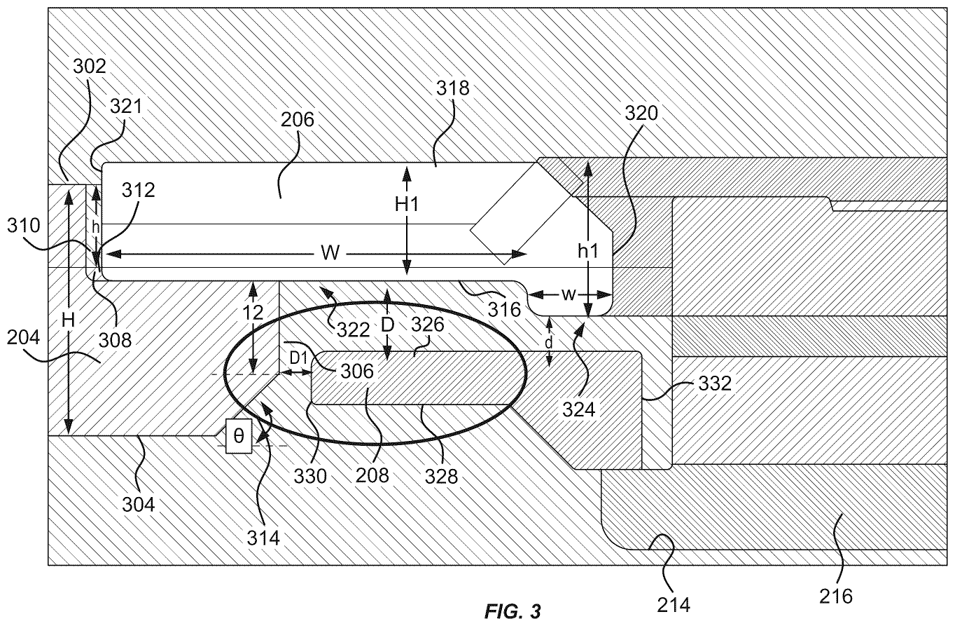

FIG. 3 illustrates a portion of flow control ring assembly 202 in greater detail. In particular, FIG. 3 illustrates a cross-sectional view of a portion of flow control ring assembly 202.

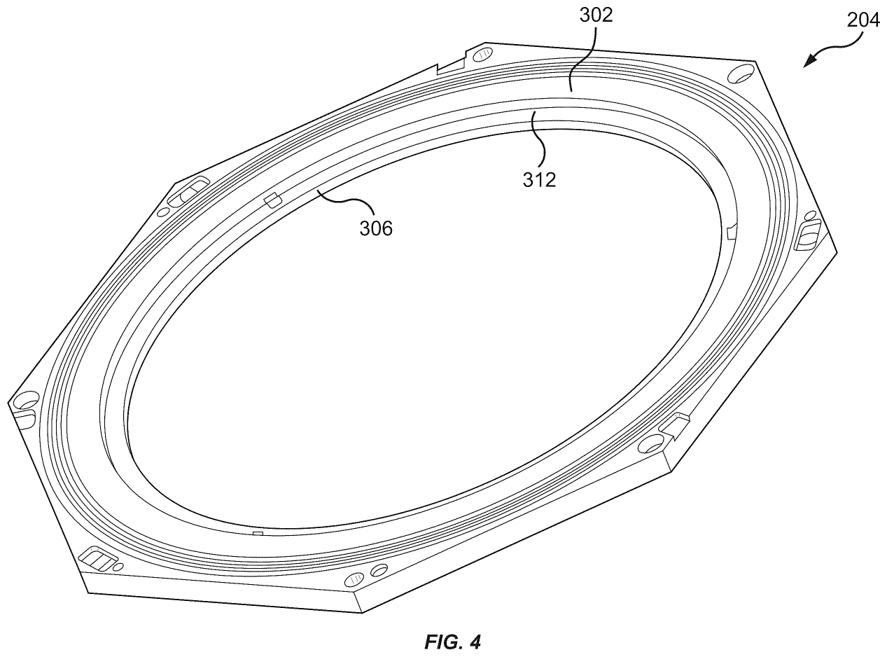

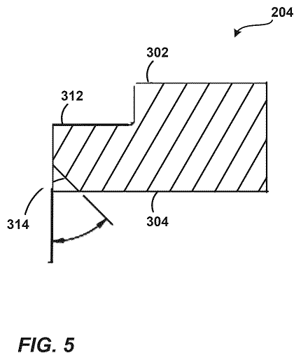

As illustrated in FIGS. 2-5, spacer plate 204 includes a spacer plate top surface 302, a spacer plate bottom surface 304, and an (e.g., substantially annular) inner spacer plate surface 306 therebetween. Spacer plate 204 further includes a (e.g., substantially annular) ledge 308 defined by an inner ledge surface 310 extending from spacer plate top surface 302 to a top ledge surface 312. Top ledge surface 312 extends between inner spacer plate surface 306 and inner ledge surface 310. A height H between spacer plate top surface 302 and spacer plate bottom surface 304 can be, for example, between about 16 mm and about 20 mm. A height h between spacer plate top surface 302 and top ledge surface 312 can be between about 5.5 mm and about 8.5 mm or between about 6 mm and about 6.5 mm. A height H2 of inner spacer plate surface 306 can be between about 4 mm and about 10 mm or between about 5.5 mm and about 6 mm.

In accordance with examples of the illustrated embodiment, spacer plate 204 includes a tapered surface 314 between inner spacer plate surface 306 and spacer plate bottom surface 304. Tapered surface 314 can form a substantially frustoconical shape. An angle θ between tapered surface 314 and spacer plate bottom surface 304 viewed in cross section can be between about 30 and 75 degrees or between about 40 and 50 degrees.

Spacer plate 204 can be formed of any suitable material. In accordance with various examples, spacer plate 204 is formed of, for example a metal, such as aluminum or a 6063 aluminum alloy.

In an example, flow control ring 206 has a substantially annular shape as viewed from, for example, the top or the bottom of flow control ring 206. In accordance with further examples, flow control ring 206 is located interior inner ledge surface 310 and rests (e.g., directly) on top ledge surface 312.

In the illustrated example, flow control ring 206 includes a flow control ring bottom surface 316, a flow control ring top surface 318, an inner perimeter surface 320 between flow control ring bottom surface 316 and flow control ring top surface 318, and an outer perimeter surface 321 between flow control ring bottom surface 316 and flow control ring top surface 318.

In accordance with various embodiments of the disclosure, flow control ring bottom surface 316 includes a first section 322 and a second section 324 interior to first section 322. As illustrated, a height H1 between the flow control ring top surface 318 and the flow control ring bottom surface 316 of the first section 322 is less than a height h1 between flow control ring top surface 318 and flow control ring bottom surface 316 of second section 324. H1 can be, for example, between about 7 and about 10 or between about 8 and about 8.5 mm; h1 can be, for example, between about 9 and about 12 or between about 10 and about 10.5 mm. A width W of first section 322 can be between about 23.5 and about 27.5 or between about 26 and about 26.5 mm; a width w of second section 324 can be between about 4 and about 8 or between about 5 and about 5.5 mm.

Flow control ring 206 can be formed of any suitable material. By way of examples, flow control ring 206 is formed of quartz.

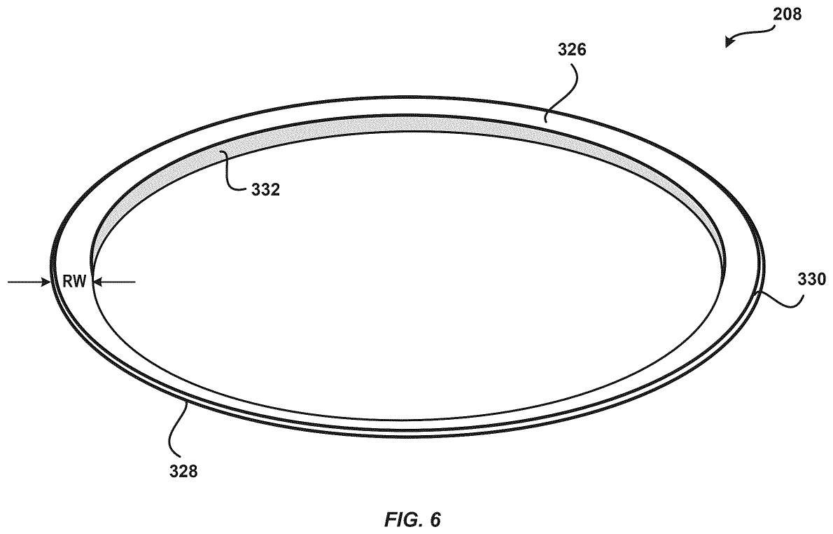

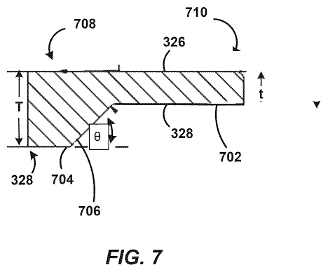

As illustrated in FIGS. 2, 3, and 6 chamber isolation ring 208 is positioned radially interior spacer plate 204 and below flow control ring bottom surface 316. FIGS. 6 and 7 illustrate exemplary chamber isolation ring 208 in more detail. In this example, chamber isolation ring 208 includes a substantially planar chamber isolation ring top surface 326 and a chamber isolation ring bottom surface 328.

In accordance with examples, a distance D between flow control ring bottom surface 316 (e.g., in first section 322) and the chamber isolation ring top surface 326 is between about 2 and about 5 mm or between about 2.5 and about 3 mm. In accordance with further examples, a distance d between flow control ring bottom surface 316 in second section 324 and chamber isolation ring top surface 326 is between about 2 and about 5 mm or between about 2.5 and about 3 mm. A distance D1 between a chamber isolation ring outer surface 330 and inner spacer plate surface 306 can be between about 3 and about 16 mm or between about 4 and about 14 mm.

Chamber isolation ring 208 includes a chamber isolation ring inner perimeter surface 332 and a chamber isolation ring outer perimeter surface 330, wherein a radial width RW between chamber isolation ring inner perimeter surface 332 and chamber isolation ring outer perimeter surface 330 is between about 13.5 and about 21.5 mm or between about 15.5 and about 20.5 mm. An inner diameter of chamber isolation ring 208 can be about 325.5 mm and/or be greater than an outer diameter of susceptor 216. An outer diameter of chamber isolation ring 208 can be between about 352.5 and about 368.5 mm or between about 356.5 and about 366.5 mm.

As best illustrated in FIG. 7, chamber isolation ring bottom surface 328 includes a first portion 702, a second portion 704, and a tapered third portion 706 therebetween. An angle θ between tapered third portion 706 and chamber isolation ring bottom surface 328 viewed in cross section can be between about 30 and 75 degrees or between about 40 and 50 degrees.

A thickness T between chamber isolation ring top surface 326 and chamber isolation ring bottom surface 328 in an inner region 708 of the chamber isolation ring (e.g., interior tapered third portion) is greater than a thickness t between chamber isolation ring top surface 326 and chamber isolation ring bottom surface 328 in an outer region 710 (e.g., exterior tapered third portion) of chamber isolation ring 208. By way of examples, a thickness between chamber isolation ring top surface 326 and chamber isolation ring bottom surface 328 in the inner region 708 can be between about 2 and about 4 mm or between about 3 and about 3.5 mm and/or a thickness between chamber isolation ring top surface 326 and chamber isolation ring bottom surface 328 in outer region 710 is between about 5 and about 8 mm or between about 7 and about 7.5 mm.

Chamber isolation ring 208 can be formed of any suitable material. By way of examples, chamber isolation ring 208 is formed of quartz.

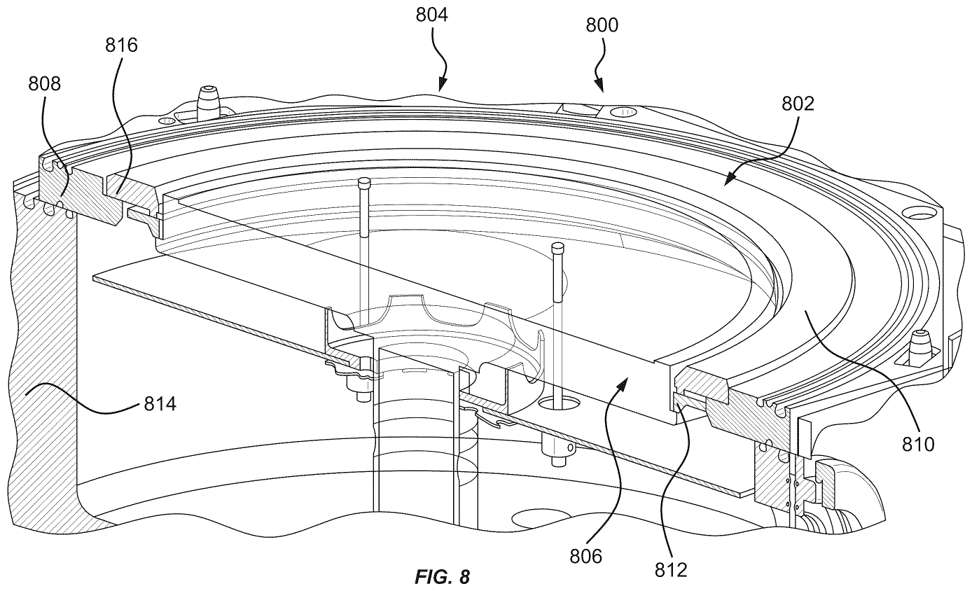

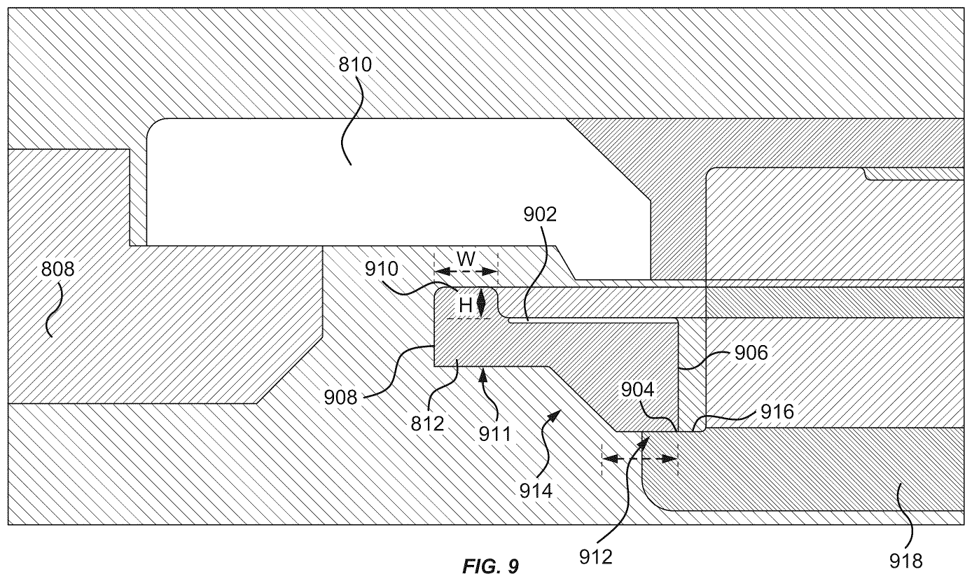

FIGS. 8 and 9 illustrate another reactor 800, including a flow control ring assembly 802, in accordance with additional examples of the disclosure. Reactor 800 can be similar to reactor 200, except for differences in flow control ring assembly 802.

Similar to reactor 200, reactor 800 includes a reaction chamber 804, a susceptor 806 within the reaction chamber 804, and flow control ring assembly 802.

Flow control ring assembly 802 includes a spacer plate 808, a flow control ring 810, and a chamber isolation ring 812. Spacer plate 808 can be the same or similar to spacer plate 204 and can be attached to a chamber wall 814 of reactor 800. Flow control ring 810 can be the same or similar to flow control ring 206 and can rest on a ledge 816 of spacer plate 808. Flow control ring assembly 802 can differ from flow control ring assembly 202 in the design of chamber isolation ring 812.

Chamber isolation ring 812 includes a chamber isolation ring top surface 902, a chamber isolation ring bottom surface 904, a chamber isolation ring inner perimeter surface 906, and a chamber isolation ring outer perimeter surface 908. Chamber isolation ring 812 is similar to chamber isolation ring 208, except chamber isolation ring 812 need not have a substantially planar chamber isolation ring top surface 902. For example, chamber isolation ring top surface 902 can include a substantially annular protrusion 910 thereon.

Annular protrusion 910 can have a width of about 3 to about 7 or about 3.5 to about 4.5 mm. An interior diameter of annular protrusion 910 can be from about 345.5 to about 365.5 or about 352 to about 363 mm. A height H of annular protrusion 910 can be between about 1 to about 3 or about 2 to about 2.5 mm. Similar to chamber isolation ring 208, chamber isolation ring bottom surface 904 of chamber isolation ring 812 includes a first portion 911, a second portion 912, and a tapered third portion 914 therebetween. Dimensions of first portion 911 portion, second portion 912, a tapered third portion 914 can be the same or similar to those described above in connection with chamber isolation ring 208. Further, chamber isolation ring 812 can be formed of the same or similar material described above in connection with chamber isolation ring 208.

As above, chamber isolation ring 812 can rest on a ledge 916 of susceptor 918, which can be the same or similar to susceptor 106. The ledge can suitably be configured to receive a portion of the flow control ring bottom surface.

In accordance with examples of the disclosure, chamber isolation ring 812 is positioned radially interior the spacer plate and below the flow control ring bottom surface, wherein a distance between the flow control ring and the chamber isolation ring (e.g., a top of protrusion) is between about 2 and about 5 mm or between about 2.5 and about 3 mm. Similar to above, a distance between a chamber isolation ring outer surface and the inner spacer plate surface can be between about 3 and about 16 mm or between about 4 and about 14 mm.

In accordance with additional embodiments of the disclosure, a method of processing a substrate is provided. Examples of the method include providing the substrate within a reaction chamber of a reactor comprising a flow control ring assembly, such as a flow control ring assembly described herein, and processing the substrate. In accordance with examples of the disclosure, the step of processing the substrate includes changing a total gas flowrate within the reaction chamber during processing of the substrate, wherein the flowrate changes from less than 100 SLM to greater than 4 SLM—e.g., in less than about 0.1 or about 1 seconds. In accordance with additional examples, the method can include forming a seal or a substantial seal between an upper chamber and a lower chamber of the reactor. In accordance with yet additional examples, a pressure within the upper chamber can change by about 40 to about 70 or about 45 to about 55 Torr during processing—e.g., in less than about 0.1 or about 1 seconds. Additionally or alternatively, a pressure difference between the upper chamber and the lower chamber can be greater than 40 or between about 45 and about 55 Torr.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A flow control ring assembly for a gas-phase reactor, the assembly comprising:
a spacer plate comprising:
a spacer plate top surface, a spacer plate bottom surface, and an inner spacer plate surface therebetween; and
a ledge defined by an inner ledge surface extending from the spacer plate top surface to a top ledge surface, wherein the top ledge surface extends between the inner spacer plate surface and the inner ledge surface;
a flow control ring comprising:
a flow control ring bottom surface;
a flow control ring top surface;
an inner perimeter surface between the flow control ring bottom surface and the flow control ring top surface; and
an outer perimeter surface between the flow control ring bottom surface and the flow control ring top surface; and
a chamber isolation ring positioned radially interior the spacer plate and below the flow control ring bottom surface, the chamber isolation ring comprising a substantially planar chamber isolation ring top surface and a chamber isolation ring bottom surface.

2. The flow control ring assembly of claim 1, wherein the spacer plate comprises a tapered surface between the inner spacer plate surface and the spacer plate bottom surface.

3. The flow control ring assembly of claim 1, wherein a height between the spacer plate top surface and the spacer plate bottom surface is between about 16 and about 20 mm.

4. The flow control ring assembly of claim 1, wherein a height between the spacer plate top surface and the top ledge surface is between 5.5 mm and about 8.5 mm or between about 6 mm and about 6.5 mm.

5. The flow control ring assembly of claim 1, wherein a distance between the flow control ring bottom surface and the chamber isolation ring top surface is between about 2 and about 5 mm or between about 2.5 and about 3 mm.

6. The flow control ring assembly of claim 1, wherein the flow control ring bottom surface comprises a first section and a second section interior to the first section, wherein a height between the flow control ring top surface and the flow control ring bottom surface of the first section is less than a height between the flow control ring top surface and the flow control ring bottom surface of the second section.

7. The flow control ring assembly of claim 6, wherein a distance between the flow control ring bottom surface in the second section and the chamber isolation ring top surface is between about 2 and about 5 mm or between about 2.5 and about 3 mm.

8. The flow control ring assembly of claim 1, wherein a distance between a chamber isolation ring outer surface and the inner spacer plate surface is between about 3 and about 16 mm or between about 4 and about 14 mm.

9. The flow control ring assembly of claim 1, wherein the chamber isolation ring bottom surface comprises a first portion, a second portion, and a tapered third portion therebetween.

10. The flow control ring assembly of claim 1, wherein the chamber isolation ring comprises a chamber isolation ring inner perimeter surface and a chamber isolation ring outer perimeter surface, wherein a radial width between the chamber isolation ring inner perimeter surface and the chamber isolation ring outer perimeter surface is between about 13.5 and about 21.5 mm or between about 15.5 and about 20.5 mm.

11. The flow control ring assembly of claim 1, wherein a thickness between the chamber isolation ring top surface and the chamber isolation ring bottom surface in an inner region of the chamber isolation ring is greater than a thickness between the chamber isolation ring top surface and the chamber isolation ring bottom surface in an outer region of the chamber isolation ring.

12. The flow control ring assembly of claim 11, wherein the thickness between the chamber isolation ring top surface and the chamber isolation ring bottom surface in the inner region is between about 2 and about 4 mm or between about 3 and about 3.5 mm.

13. The flow control ring assembly of claim 11, wherein the thickness between the chamber isolation ring top surface and the chamber isolation ring bottom surface in the outer region is between about 5 and about 8 mm or between about 7 and about 7.5 mm.

14. The flow control ring assembly of claim 1, wherein a height of the inner spacer plate surface is between about 7.5 and about 14.5 mm or between about 9.5 and about 14 mm.

15. A reactor comprising:
a reaction chamber;
a susceptor within the reaction chamber; and
a flow control ring assembly comprising:
a spacer plate comprising:
a spacer plate top surface, a spacer plate bottom surface, and an inner spacer plate surface therebetween;
a ledge defined by an inner ledge surface extending from the spacer plate top surface to a top ledge surface, wherein the top ledge surface extends between the inner spacer plate surface and the inner ledge surface;
a flow control ring comprising:
a flow control ring bottom surface;
a flow control ring top surface;
an inner perimeter surface between the flow control ring bottom surface and the flow control ring top; and
an outer perimeter surface between the flow control ring bottom surface and the flow control ring top; and
a chamber isolation ring positioned radially interior the spacer plate and below the flow control ring bottom surface, wherein a distance between the flow control ring and the chamber isolation ring is between about 2 and about 5 mm.

16. The reactor of claim 15, wherein the chamber isolation ring comprises a substantially planar chamber isolation ring top surface.

17. The reactor of claim 15, wherein a distance between a chamber isolation ring outer surface and the inner spacer plate surface is between about 3 and about 16 mm or between about 4 and about 14 mm.

18. The reactor of claim 15, wherein the chamber isolation ring rests on the susceptor.

19. The reactor of claim 18, wherein the susceptor comprises a susceptor ledge configured to receive a portion of the flow control ring bottom surface.

20. A method of processing a substrate, the method comprising:
providing the substrate within a reaction chamber of a reactor comprising the flow control ring assembly of claim 1; and
changing a total gas flowrate within the reaction chamber during processing of the substrate, wherein the flowrate changes from less than 100 SLM to greater than 4 SLM.
